(19) United States
(12) Patent Application Publication
(10) Pub. No.: US 2006/0131588 A1
(43) Pub. Date: Jun. 22, 2006

(54) Electrode and electron emission applications for n-type doped nanocrystalline materials

(76) Inventors: Dieter M. Gruen, Downers Grove, IL (US); Olando H. Auciello, Bollingbrook, IL (US); Greg M. Swain, East Lansing, MI (US); Ming Ding, Beijing (CN); John A. Carlisle, Plainfield, IL (US); Alan R. Krauss, Naperville, IL (US); Julie R. Krauss, Naperville, IL (US)

Correspondence Address: HARRY M. LEVY;EMRICH & DITHMAR, LLC, 125 SOUTH WACKER DRIVE, SUITE 2080, CHICAGO, IL, 60606-4401, US

(21) Appl. No.: 10/398,329

(22) PCT Filed: Oct. 9, 2001
(86) PCT No.: PCT/US01/31388

§ 371 Date: Oct. 17, 2005

(51) Int. Cl. H01L 31/0312

(52) U.S. Cl. 257/77

(57) ABSTRACT

An electrode having a surface of an electrically conducting ultrananocrystalline diamond having not less than 10¹⁹ atoms/cm³ nitrogen with an electrical conductivity at ambient temperature of not less than about 0.1 (Ω·cm)⁻¹ is disclosed as is a method of remediating toxic materials with the electrode. An electron emission device incorporating an electrically conducting ultrananocrystalline diamond having not less that 10¹⁹ atoms/cm³ nitrogen with an electrical conductivity at ambient temperature of not less than about 0.1 (Ω·cm)⁻¹ is disclosed.

### RELATED APPLICATIONS

This application, pursuant to 37 C.F.R. 1.78(c), claims priority based on provisional application Ser. No. 60/239,173 filed on Oct. 9, 2000 and provisional application Ser. No. 60/314,142 filed on Aug. 22, 2001.

### CONTRACTUAL ORIGIN OF THE INVENTION

The United States Government has rights in this invention pursuant to Contract No. W-31-109-ENG-38 between the U.S. Department of Energy (DOE) and The University of Chicago representing Argonne National Laboratory.

### BACKGROUND OF THE INVENTION

The use of diamond as an electronic material has remained elusive for many years. The problem lies in the difficulty of finding a way to dope diamond so that it's ambient temperature conductivity and carrier mobility are sufficiently high to make diamond-based devices work at room or ambient temperature. Traditional doping with nitrogen does not work, since nitrogen forms a deep donor level 1.7 eV below the conduction band, and thus is not thermally activated at room temperature. This is due to the fact that nitrogen is very reluctant to insert into the diamond lattice, and all efforts to dope microcrystalline diamond with electrically active nitrogen have to date met with very limited success.

The inventors and others at Argonne National Laboratory have worked for several years developing the use of microwave plasma enhanced chemical vapor deposition (MPCVD) to produce ultrananocrystalline diamond (UNCD) thin films. These films are grown using argon-rich plasmas rather than the traditional hydrogen-rich plasmas, which are routinely used to grow microcrystalline diamond films, as disclosed in U.S. Pat. No. 5,462,776, the disclosure of which is incorporated by reference.

The UNCD films have grain boundaries are almost atomically abrupt (−0.5 nm). and have been measured on the average of 0.3 to 0.4 nm. These UNCD films exhibit exceptional mechanical, and tribological properties, the latter particularly applicable to the development of a new microelectromechanical system (MEMS) technology based on UNCD. For purposes of this application, UNCD shall be defined as films grown from C₂ dimers, as set forth in the '776 patent.

### SUMMARY OF THE INVENTION

This invention relates to n-type doping of UNCD films, that is films with average grain size of less than about 15 nm, as opposed to films with larger grain sizes, such as microcrystalline or nanocrystalline diamond. When nitrogen gas was added to gas mixtures used to grow UNCD, the conductivity of the films unexpectedly increased by more than five orders of magnitude, while the grain boundaries and the grain size become larger.

Accordingly, it is an object of the present invention to provide an electrically conducting ultrananocrystalline diamond film having about 10¹⁹ atoms/cm³ nitrogen with an electrical conductivity of not less than about 0.1 Ω⁻¹ cm⁻¹ having a voltammetric response in the presence of Fe(CN)₆^{-3/-4}, Ru(NH₃)₆^{+2/+3}, methyl viologen and 4-tert-butylcatechol similar to high quality microcrystalline diamond, indicating that the nanocrystalline films are active without any conventional pretreatment, and posses semimetallic electronic properties over a potential range from 0.5 to −1.5 V (vs. SCE). Another object of the present invention is to provide an electrically conducting ultrananocrystalline diamond film of the type set forth useful as diamond film electrodes with continuous pin-hole free surface at thickness in the order of about 750 Å to about 2000 Å in electrochemical cells operating at over voltages of about 2.5 volts to degrade or destroy organic contaminants.

Another object of the invention is to provide field emission devices using the nitrogen doped UNCD films disclosed herein as flat panel displays, cold cathode devices in traveling wave tubes, satellite thrusters, x-ray machines and devices.

The invention consists of certain novel features and a combination of parts hereinafter fully described, illustrated in the accompanying drawings, and particularly pointed out in the appended claims, it being understood that various changes in the details may be made without departing from the spirit, or sacrificing any of the advantages of the present invention.

### BRIEF DESCRIPTION OF THE DRAWINGS

For the purpose of facilitating an understanding of the invention, there is illustrated in the accompanying drawings a preferred embodiment thereof, from an inspection of which, when considered in connection with the following description, the invention, its construction and operation, and many of its advantages should be readily understood and appreciated.

FIG. 1(a) is a graphical representation of the relationship of the concentration of CN radicals as a function of nitrogen in the plasma;

FIG. 1(b) is a graphical representation of the relationship of the concentration of C₂ radicals as a function of nitrogen in the plasma;

FIG. 2(a) is a graphical representation of the relationships of total nitrogen content (left axis) and room-temperature conductivity (right axis) in a UNCD film as a function of nitrogen in the plasma;

FIG. 2(b) is an Arrhenius plot of conductivity data obtained in the temperature range 300-4.2 K for a series of UNCD films synthesized using different nitrogen concentrations in the plasma as shown;

FIG. 3 is a graphical representation of relationship of the concentration of nitrogen incorporated in the UNCD films versus the percent nitrogen in the feed gas of the plasma;

FIGS. 4(a)-(d) are UV Raman spectra of UNCD films: a) without nitrogen in the gas chemistry, and with b) 2%, c) 10% and d)20% nitrogen, showing that all the nitrogen-added films have approximately the same sp²;sp³ ratio, which is increased 25-30% over the non-nitrogen film;

FIG. 5 is EELS spectra of a UNCD film with 2% nitrogen and without nitrogen in the plasma, showing a distinct shoulder in the nitrogen film indicating sp² bonded carbon;

FIGS. 6(a)-6(d) Low and high resolution TEM micrographs of a.) 0% N₂ b.) 5% N₂ UNCD, c.) 10% N₂ UNCD, and d.) 20% N₂ UNCD films. Low resolution micrographs are on the left, high resolution on the right. The figures are scaled so that the low resolution micrographs are 350 nm by 350 nm and the high resolution ones are 35 nm by 35 nm;

FIG. 7 is a graphical representation of the relationship of the onset field emission as a function of the percent nitrogen in the plasma;

FIGS. 8(A)-(B) are graphical representations of the Visible Raman spectra of (A) nanocrystalline diamond films deposited from 0, 2, 4 and 10% N₂ in the source gas mixture and (B) is a microcrystalline, boron-doped diamond film;

FIG. 9 is a graphical representation of a UV Raman spectra of nanocrystalline diamond films deposited from 1, 5 and 10% N₂ in the source gas mixture;

FIGS. 10(A)-(B) are graphical representations of SIMS data for nanocrystalline diamond films. (A) Plot of the N/C atomic concentration ratio versus the percentage of N₂ added to the source gas mixture, and (B) depth profiles for the atomic carbon and nitrogen concentrations in a film deposited from 1% CH₄/5% N₂/95% Ar.

FIG. 11 are cyclic voltammetric i-E curves for nanocrystalline diamond thin films deposited from 1% CH₄/1% N₂/98% Ar, 1% CH₄/2% N₂/97% AR, 1% CH₄/4% N₂/95% Ar and 1% CH₄/5% N₂/94% Ar. Electrolyte: 1M KCl. Scan rate: 0.1 V/s.

FIGS. 12(A)-(B) are cyclic voltammetric i-E curves for nanocrystalline diamond thin films deposited from (A) 1% CH₄/99% Ar, (B) 1% CH₄/2% N₂/97% Ar, (c) 1% CH₄/4% N₂/95% Ar and (D) 1% CH₄/5% N₂/94% Ar. Electrolyte: 0.1 M HClO₄. Scan rate: 0.1 V/s;

FIGS. 13(A)-(B) are graphical representation of cyclic voltammetric data for nanocrystalline diamond thin films. (A) Plots of the oxidation peak current versus the scan rate^{1/2}. Analyte concentration: 1 mM. Electrolyte: 1M KCl. (B) Plots of the oxidation peak current versus the analyte concentration. Electrolyte: 1M KCl. Scan rate: 0.1 V/s;

FIG. 14 show oxidation-reduction reactions for a variety of compounds; and

FIG. 15 is a schematic diagram of a field-emission cold cathode using the n-doped UNCD.

### DESCRIPTION OF THE PREFERRED EMBODIMENT

This invention relates to the incorporation of dopants into UNCD thin films, in particular, the incorporation of nitrogen via the addition of N₂ gas to the carbon containing noble gas plasma. When we use CH₄ it is a short hand for the sources of carbon set forth above, and when we use argon it is a short hand for any noble gas. We have shown that nitrogen-containing UNCD thin films can be used as electrochemical electrodes over a 4 eV potential range and exhibit semimetal-like electronic properties. A possible explanation is that nitrogen may introduce changes in morphology and electronic structure within the GBs that may lead to enhanced electronic transport, since simulation indicate that introduction of nitrogen into high-angle twist diamond GBs is energetically favored by 3-5 eV compared to substation into the grains.

The inventive films were grown on a variety of metals and non-metals using microwave plasma chemical vapor deposition with gas mixtures of Ar/CH₄(1%-2%)/N₂(1-20%) at total pressures of 100 Torr and 800 W of microwave power, while the substrates were maintained at temperatures from about 350 to 800° C.

Essentially all the grains of UNCD films have the stated grain sizes, and by essentially all we mean greater than about 90% and preferably greater than about 95%. Moreover, UNCD films may be produced using up to about 2% by volume of CH₄ or a precursor thereof or C₂H₂ or a precursor thereof or a C₆₀ compound. UNCD films exhibit a number of interesting materials properties, including enhanced field emission, and electrochemical, as well as mechanical, tribological, and conformal coating properties suitable for microelectromechanical system devices.

The number densities of the C₂ and CN radicals formed in the plasma increase proportionally with nitrogen content in the plasma up to 5%, as measured by absorption spectroscopy. Secondary ion mass spectroscopy (SIMS) data show that the content of nitrogen in the film saturates at about 1×10¹⁹ atoms/cm³ (−0.2% total nitrogen content in the film) when the nitrogen concentration in the plasma is 5%. The conductivity at room temperature increases dramatically with nitrogen concentration, from 0.016 (1% N₂) to 143 Ω⁻¹ cm⁻¹ (20% N₂). This is to be compared with the best values reported previously: 10⁻⁶ Ω⁻¹ cm⁻¹ for nitrogen-doped microcrystalline diamond and 0.33 Ω⁻¹ cm⁻¹ for phosphorous-doped microcrystalline diamond films.

Grain boundaries (GBs) in UNCD are believed to be high-energy, high-angle GBs. Molecular dynamics simulations of diamond (100) twist GBs have revealed that they have a large fraction os sp²-bonded atoms. Tight-binding calculations for 13 and Σ29 GBs revealed that electronic states are introduced into the band gap of the UNCD films, due to dangling bonds and π-bonded carbon atoms in the GBs.

Temperature dependent conductivity and Hall measurements are both indicative of multiple, thermally activated conduction mechanisms with effective activation energies of <0.1 eV. This behavior is very similar to highly-boron-doped microcrystalline diamond. However, the inventors do not believe that nitrogen is acting in the manner boron does. It is believed that conduction occurs via the grain boundaries and not the grains. Tight-binding molecular dynamic simulations have shown that nitrogen incorporation into the high-angle grain boundaries is favored by 3-5 eV over substitution into the bulk. Nitrogen increases the amount of three-fold coordinated carbon atoms in the grain boundaries (GB) and leads to additional electronic states near the Fermi level. The inventors believe that GB conduction involving carbon πEr-states in the GB is responsible for the high conductivities. It has been shown that many of these states near the Fermi-level are delocalized over several carbon nearest neighbors.

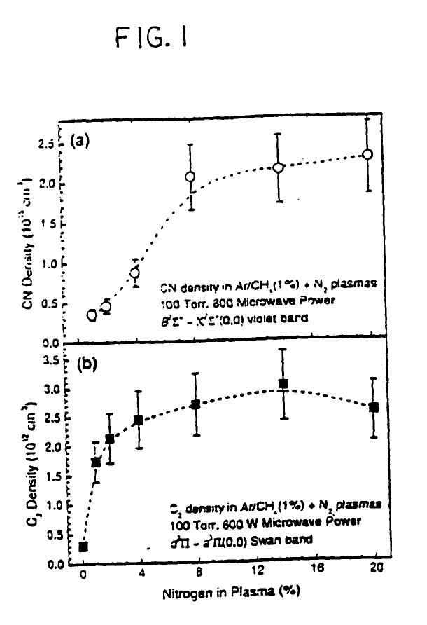

Some of the inventive films were grown either on Si(100) or insulating silica (SiO₂) substrates (for transport measurements) at 800° C., using a CH₄(1%)/Ar/N₂ gas mixture at a total gas pressure of 100 Torr and 800 W microwave power. However, other substrates, such as various metals and non-metals may also be used. The average C₂ and CN radical densities in the plasma were determined in situ using absorption spectroscopy. These results are shown in FIGS. 1(a) and (b). Equivalent widths of rotational lines within the d³ Pa³P(0,0) Swan band of C₂ and the B²S⁺-X²⁺(0,0) violet band of CN were integrated and converted into column densities using published values of the band oscillator strengths weighted by the appropriate Hönl-London and Boltzmann factors using a gas temperature of 1600 K, which had been determined previously by rotational analysis.

As shown in FIGS. 1(a) and (b) the densities of both the C₂ and CN radicals increase substantially as N₂ gas is added to the plasma, while their ratio changes as well. For small additions of N₂ (1%-5%), the effect is to increase the density of C₂ dimers by one order of magnitude. As the N₂ content approaches 8%, the relative density of C₂ to CN decreases by a factor of 5. This trend in the data is also reflected by accompanying changes in film morphology, total nitrogen content, and conductivity, as discussed below.

High-resolution transmission electron micrographs (HRTEM) from UNCD films synthesized using either 1% or 20% N₂ in the plasma show substantial microstructural changes, as shown in FIG. 6(a)-6(d). For low-nitrogen partial pressures (<5%) the morphology of the films remains largely unchanged, with the average grain size and average GB widths increasing only slightly. However, in films made using 10% or more N₂, both the average grain size and average GB widths increase significantly, to 12 and 1.5 nm, respectively. Films made using 20% N₂ have average grain sizes about 15 nm and average GB width of 2 nm. The contrast in the HRTEM images between the GBs and the diamond grains suggests that the GBs are less dense than the grains. We believe this is evidence of an increase in sp² bonding in these regions of the films.

The inventive films have a substantially different microstructure than prior art films. For instance, Zhou et al. in J. Appl. Phys. 82(9), 1 Nov. 1997 report a nanocrystalline thin film grown from N₂/CH₄ microwave plasma. The Zhou et al. films were grown in an entirely different plasma than the inventive materials described herein. The Zhou et al. plasma contained no nobel gas, whereas the predominant portion of the plasma used to grow the inventive material is a nobel gas. With N₂ present in the 20-25 volume percent range and carbon present in the 2 atom percent range, the nobel gas would be present in an amount of at least 73 volume percent for the inventive process and materials produced thereby.

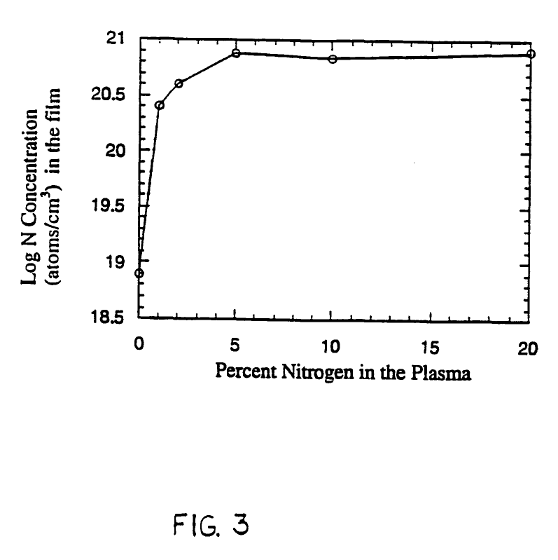

At stated, the Zhou et al. material does not have the same microstructure as the inventive films. The inventive materials have a clear grain+GB morphology, whereas the films studies by Zhou et al. do not, as shown in FIG. 3 of that paper. Furthermore, the average grain size of the Zhou et al. material is believed to be substantially larger (about 30-50 nm, based again on FIG. 3 of their paper) than the average grain size of the inventive material, which is between about 2 nm or less to about 15 nm.

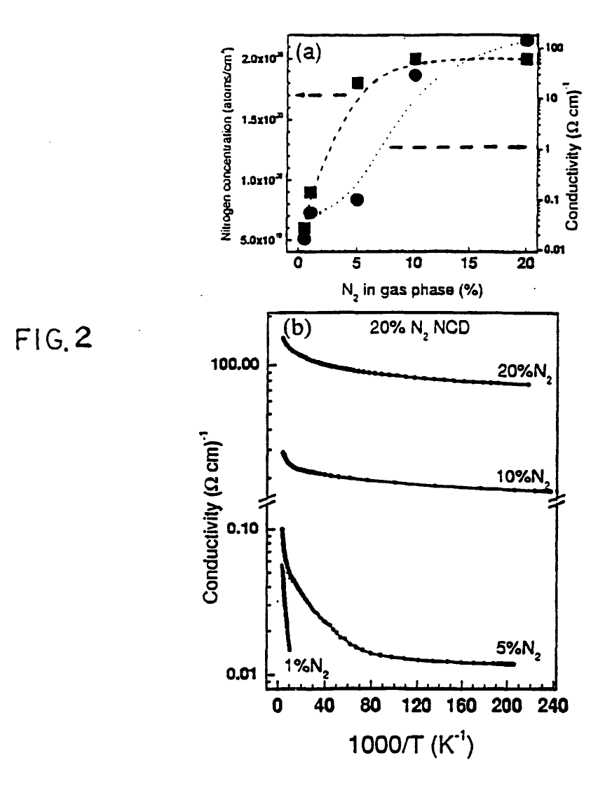

Four-point-probe conductivity measurements in the temperature range 300-4.2 K were performed using both linear and van der Pauws geometries. These results are shown in FIGS. 2(a) and (b). In addition, FIG. 2(a) shows secondary ion mass spectroscopy (SIMS) data for the total nitrogen content in the films as a function of the percentage of N₂ gas added to the plasma. Along with these data is a plot of the room-temperature conductivities for the same films. The SIMS data indicate that the nitrogen content in the films initially increases but then saturates at −2×10²⁰ atoms/cm⁻³ for 5% N₂ in the plasma, which corresponds to about 0.2% total nitrogen content in the film. The increase in room-temperature conductivity is both dramatic and unexpected, increasing from 0.016 Ω⁻¹cm⁻¹ (for 1% N₂) to 143 Ω⁻¹ cm⁻¹ (for 20% N₂), which represents an increase by roughly five orders of magnitude over undoped UNCD films. The latter value is much higher than any other previously reported for n-type diamond and is comparable to heavily boron-doped p-type diamond. Materials made with source gases having up to about 23-25% N₂ show substantially conductivity, but at 25% N₂ it is believed the conductivity begins to decrease.

Temperature-dependent conductivity data in the range of 300-4.2 K are shown in the Arrhenius plot in FIG. 2(b). These data are remarkable for several reasons. First, it is clear that these films exhibit finite conduction for temperatures even as low as 4.2 K. This behavior is also seen in heavily boron-doped diamond thin films. Also, these curves are clearly not simple straight lines in the Arrhenius plot, which is indicative of multiple, thermally activated conduction mechanism with different activation energies. These curves can be modeled by a summation of exponential functions as has been done in other studies where impurity conduction due to boron doping is dominant over the normal band conduction in doped single-crystal and polycrystalline diamond. We do not, however, expect that the present case is an example of degenerate doping of UNCD with nitrogen.

Hall measurements (mobility, carrier concentration, Hall coefficient) have been made on two of the UNCD films grown with 10% and 20% nitrogen in the plasma. The carrier concentrations for the 10% and 20% N₂ samples, were found to be 2.0×10¹⁹ and 1.5×10²⁰ cm⁻³, respectively. The latter concentration is two orders of magnitude larger than any previous result for n-type diamond, and comparable to the carrier density in heavily boron-doped diamond. We also find reasonable high room-temperature carrier mobilities of 5 and 10 cm²/Vs for the 10% and 20% films, respectively. The negative value of the Hall coefficients indicates that electrons are the majority carriers in each of these films.

It is seen therefore that the electrical conductivity of a nitrogen doped UNCD material can be systematically and reproducibly adjusted, permitting a material or film to be made with a predetermined electrical conductivity. For instance, adding 5% nitrogen results in a material having a conductivity of about 0.1 (Ω cm)⁻¹ while adding 10% nitrogen results in a material having a conductivity of about 30 (Ω cm)⁻¹, see FIGS. 2 (a)(b). The ability to predetermine and vary the conductivity of UNCD materials is entirely new and unexpected. Previously materials were made and then their conductivities were measured, but there was no method of making materials having a specifically desired conductivity, until this invention.

We believe that conduction occurs via the grain boundaries based on the above data and the following considerations. Nitrogen in microcrystalline diamond thin films usually forms a deep donor level with an activation energy of 1.7 eV. Therefore, it is unlikely that the enhanced conductivity in UNCD is due to nitrogen doping of the grains as previously believed, but rather at the grain boundaries. With the theoretical calculations indicating that nitrogen is favored by 3-5 eV for GB doping, we believe that the nitrogen in these films is present predominantly in the GBs and not within the grains. Using ultrananocrystalline diamond rather than microcrystalline or even nanocrystalline diamond because the smaller the grains, the larger number of grain boundaries and it is at the grain boundaries that the effective nitrogen doping occurs.

Our tight-binding calculations assuming nitrogen substitution in the GBs shows that new electronic states associated with carbon Tr bonds and dangling bonds are introduced into the fundamental gap, and that there are unoccupied states available near the Fermi level. When nitrogen is introduced into the GBs, the associated carbon dangling-bond state is above the Fermi level and donates electron-to-carbon defect states near the Fermi level, causing it to shift upward (i.e., toward the conduction band). Thus, it is not unreasonable to believe that nearest-neighbor hopping or other thermally activated conduction mechanisms could occur in the GBs and result in greatly enhanced electron transport. The conduction may occur via the new carbon states in the band gap.

Other films produced according to this invention were prepared by mechanically polishing n-type silicon wafers (resistivity 0.001-1.0 Ω-cm) with 0.1 micron diamond powder for approximately 10 minutes. The Si substrates were then placed in the PECVD chamber. The films were grown at 800° C., 100 Torr total pressure, 100 sccm total gas flow rate, and 800 W microwave power. These conditions are by way of example only and are not meant to limit the invention. It is now within the skill of the art to produce ultrananocrystalline diamond using a variety of conditions and techniques. The content of the source gas mixture was changed by successively adding N₂ to replace argon in 1% CH₄/99% Ar plasmas. Films with 1% CH₄ and 0% N₂/99% Ar to 20% N₂/79% Ar were grown and were approximately one micron in thickness. The films were then characterized using secondary ion mass spectrometry (SIMS), transmission electron microscopy (TEM), UV Raman spectroscopy, and scanning electron microscopy (SEM).

SIMS analysis was performed using a high-mass resolution SIMS. It is necessary to examine the CN ion because the hydrocarbon masses interfere with the positive nitrogen secondary ions, and there are no stable nitrogen negative secondary ions. High mass resolution is required to analyze CN (26.003 amu) to distinguish it from C₂H₂ (26.015 amu). FIG. 3 displays the secondary ion mass spectroscopy results as nitrogen concentration in the film versus the percent nitrogen in the plasma during film growth. Since the base pressure of the PECVD system is approximately 1 mTorr, about 8×10¹⁸ atoms/cm³ of nitrogen, slightly less than 0.01 atomic percent, is present in the UNCD film due to atmospheric nitrogen contamination. With the addition of 1% N₂ to the plasma, the concentration of nitrogen in the film increases an order of magnitude to 2.5×10²⁰ atoms/cm³, and continues to rise until about 5% nitrogen is added to the plasma. No further increase in nitrogen in the film is observed even when 20% N₂ is added to the plasma. The concentration of nitrogen incorporated in the film

therefore saturates at about 8×10²⁰ atoms/cm³ TEM electron diffraction patterns for a film without added nitrogen and one with 2% nitrogen can be completely indexed on the diamond lattice, no other crystalline phase was found. The grain size distribution of such films is on the order of 3-15 nm.

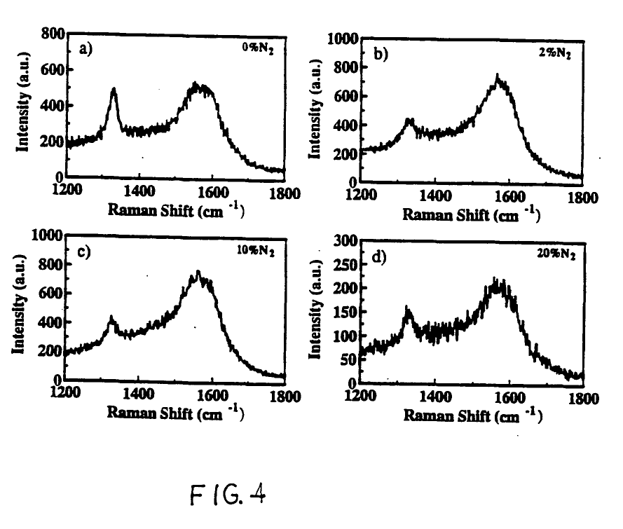

FIGS. 4(a)-(d) show the UV Raman spectra of UNCD films with varying degrees of nitrogen content. The introduction of nitrogen results in an increase in the peak at 1580 cm⁻¹ relative to the peak at 1332 cm⁻¹, which is the phonon peak for diamond. The relative ratio of sp² to sp³, however, remains roughly independent of the nitrogen concentration. By integrating the areas under the Raman curves in FIGS. 4(a)-(b), the present increase in the sp²:sp³ ratio for the nitrogen films is calculated as 25-30%.

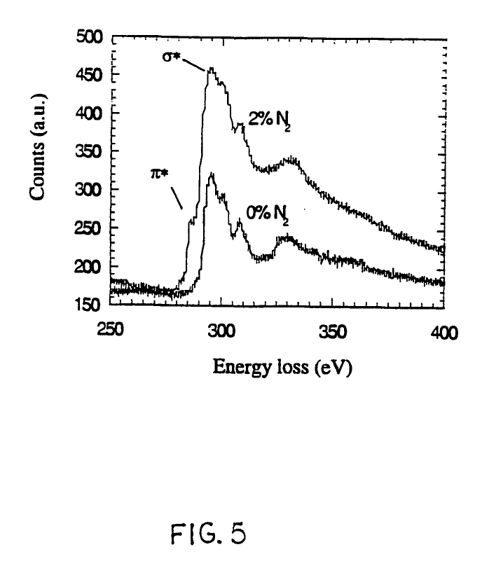

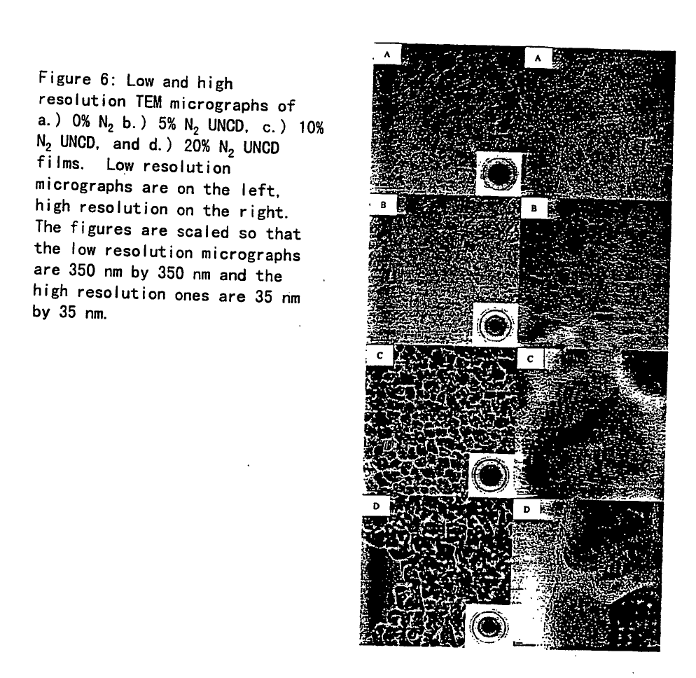

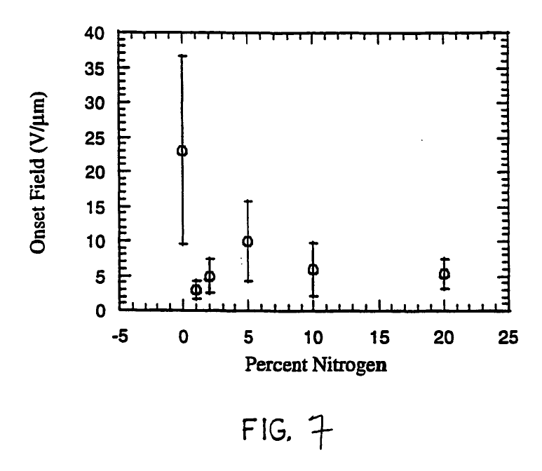

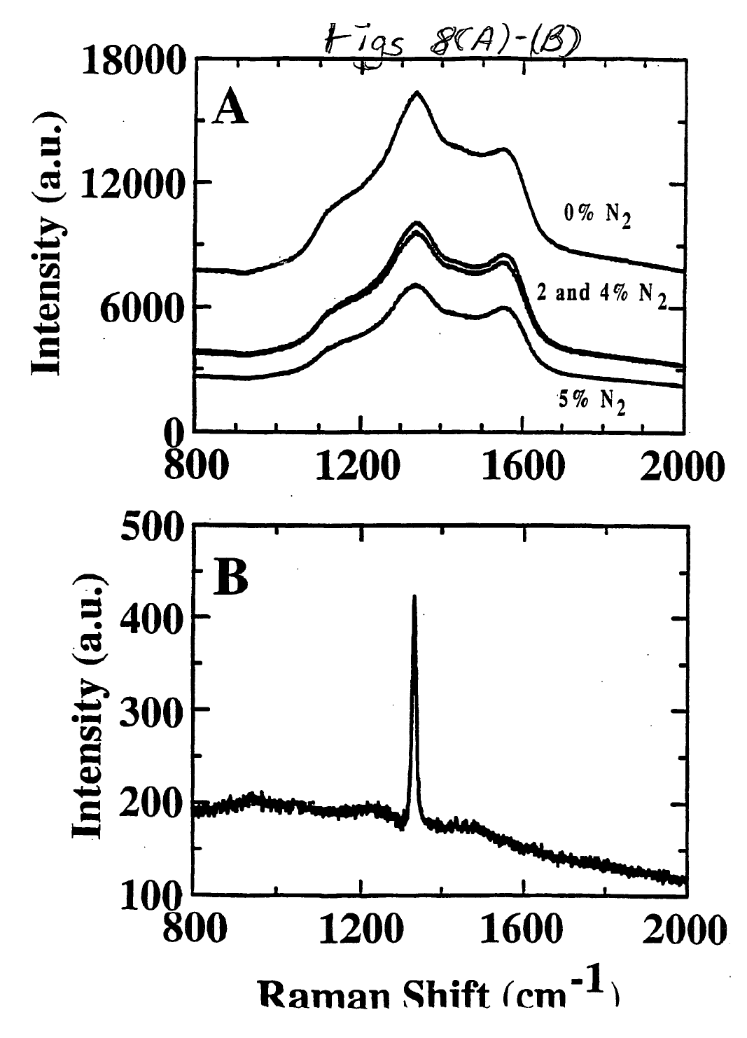

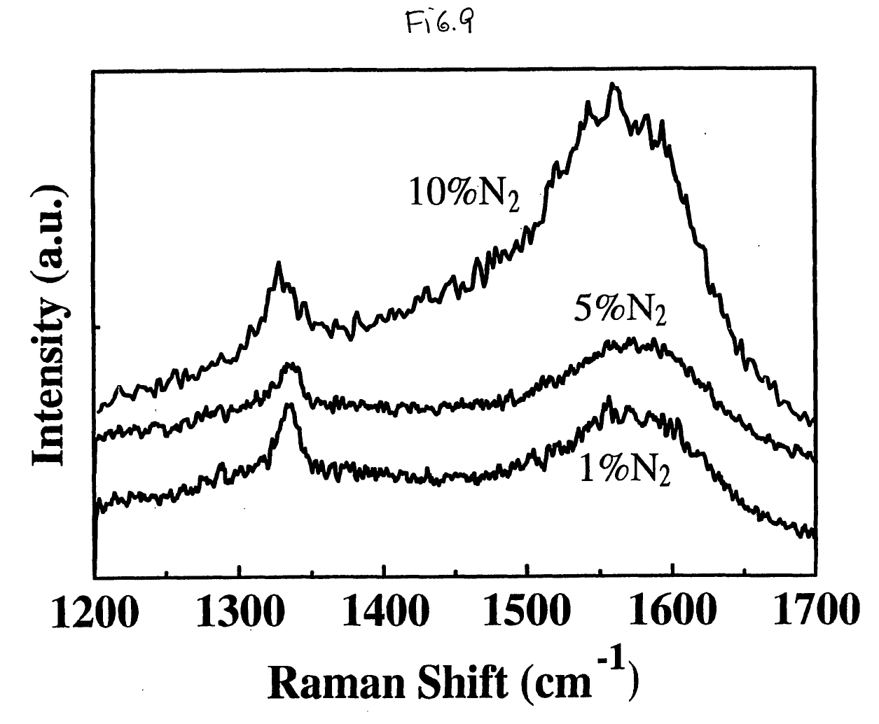

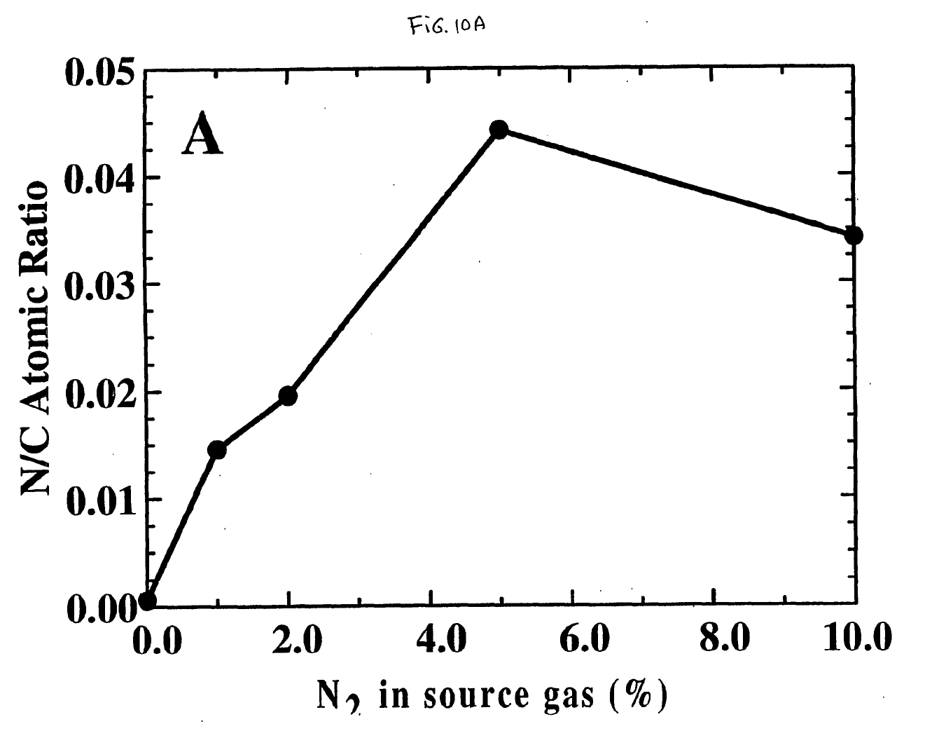

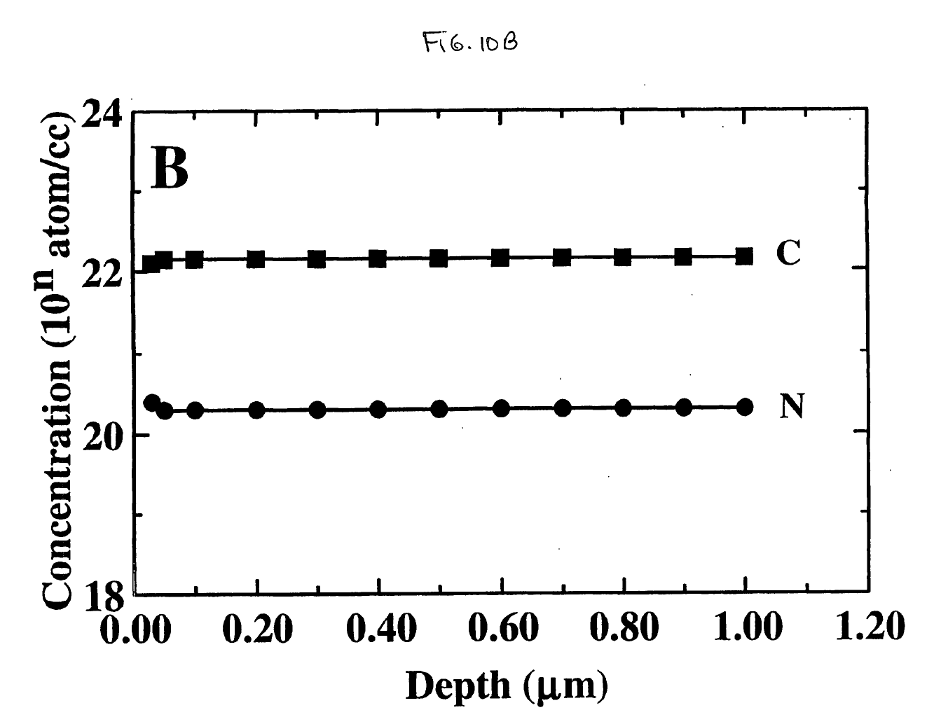

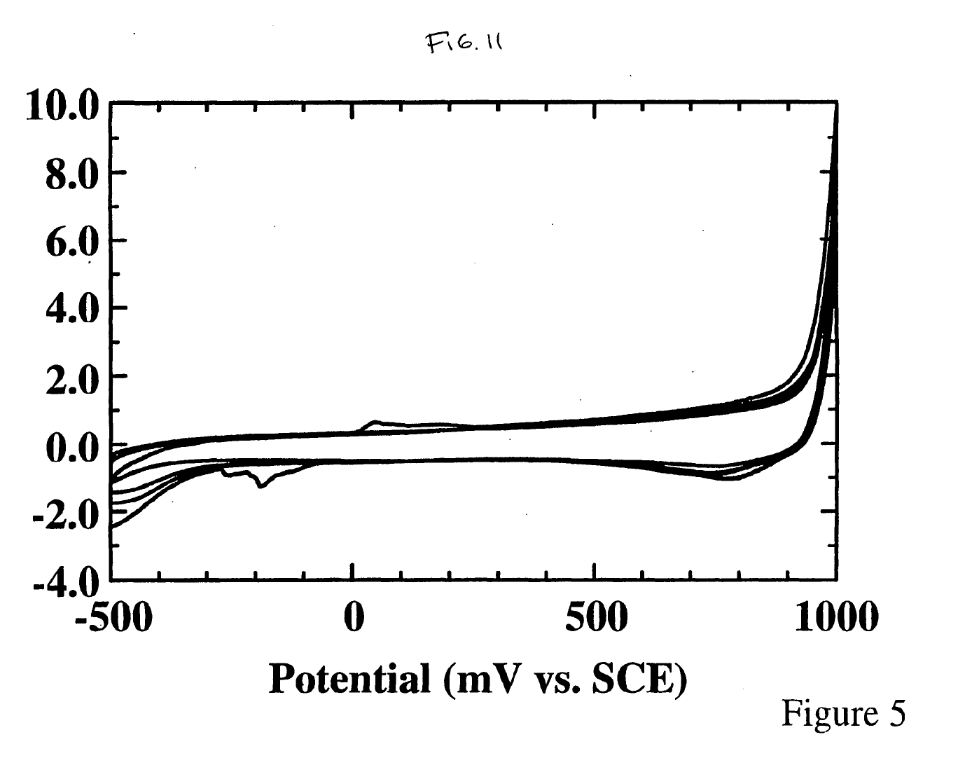

FIG. 5 shows the electron energy loss spectra (EELS) for UNCD films without nitrogen and with 2% nitrogen to the plasma, respectively. The EELS of the nitrogen-grown diamond film reveals the K-edge δ* peak at 291 and a distinct π* peak originating form the sp² carbon K edge at 286 eV. The film grown without nitrogen shows only the δ* peak by EELS measurements.

The field emission measurements were carried out on an apparatus previously described in an article published by D. Zhou et al. in J. Electrochem soc. The field emission measurements were carried out on an apparatus previously described in an article published by D. Zhou et al. in J. Electrochem Soc. 144(1997) L224, the disclosure of which is hereby incorporated by references. Briefly, a negative potential is applied to the sample, and the emission current is measured using a Keithley electrometer. A CCD camera is used to estimate the initial starting gap, typically 50 to 100 microns. The distance has been calibrated with a foil with a thickness of 500 microns. The anode is a 2.0 mm diameter tungsten probe with the edges slightly rounded to avoid edge effects. An ambient pressure of 10⁻⁸ Torr is maintained in the test chamber by a turbo molecular pump and an ion pump. The applied voltage is varied, and the collected current as a function of applied voltage is recorded on a computer system. The applied voltage divided by the gap distance yields the applied field.

The results of the field emission measurements are shown in FIG. 7. The film without added nitrogen had an average onset field of 23 V/μm, with a best onset value of 10 V/μm. The figure shows that for nitrogen containing films the average onset field required for emission immediately drops to below 5 V/μm for 1% nitrogen added to the plasma, and remains relatively constant for up to 20% N₂ in the plasma. Some film areas had onset fields as low as 2 V/μm. The measurements represent the average values of at least 12 different areas on one or two samples with the given percent nitrogen. Some of the films had a few areas that did not emit below fields of 40 V/μm. These spots were not included in the averages. In general, it was observed that several films without added nitrogen showed distinctly higher onset fields for all examined areas than the nitrogen-added films. Table 1 shows a summary of the data for all the films.

Field emitters have a wide variety of applications to multiple devices involving electron emission from fabricated field emitter sharp tips or edge structures that are localized at the center of a hole (see FIG. 15). The application of a potential between the gate electrode and the field emitter tip produces a very high field on the tip, which results in field-induced emission of electrons. Current materials used for producing the field emitter have relatively high threshold fields for emission (about 10 V/μm) and/or they exhibit unstable emission current. Undoped or n-type or p-type doped UNCD exhibit both very low threshold field (4 V/μm) and stable emission current, the two main requirements for operation of cold cathodes based on field emission.

UNCD based cold cathodes can be used in multiple applications, some of which are:

1. Field emission flat panel displays, where the electrons emitted from a high-density array of tips (FIG. 15) impact on a phosphor screen on a glass substrate located in front of the tip array. The emission from the tip array is controlled by an electronic microcircuit that provides the processing signal for image production.

2. Cold cathode for traveling wave tubes used for high power, high frequency devices included in many systems such as radar, communication devices and others.

3. Micrometer size field emission sources for fabrication of miniaturized sensors integrated in semiconductor-based sensor/actuation devices.

4. Cold cathodes for instruments based on electron emission such as mass spectrometers and field emission electron microscopes.

5. Cold cathodes for large systems such as ion beam accelerators, where the electrons are used to generate plasmas needed to produce the ion beams; X-ray sources, where the electrons are used to generate X-rays via electron impact on solid anodes.

6. Field emission sources to provide electrons for creating a plasma in a confined chamber for use as a spacecraft thruster. The impulse is provided by momentum transfer to the thruster chamber by ion expelled from the plasma.

N-type doped UNCD materials, as disclosed herein have applications to all the devices described above.

Although FIG. 15 shows one emitter, in use as is well known in the art, an array of high density emitters may be employed, as for instance in flat panel displays.

TABLE 1

| | | Nitrogen | Average Field |
|---|---|---|---|
| Percent | Surface | Concentration | Emission Onset |
| Nitrogen | Roughness | (×10²⁰ at/cc) | (V/μm) |
| 0 | 36-44 | 0.08 | 23 |
| 1 | 24 | 2.5 | 3 |
| 2 | 25 | 4.0 | 5 |
| 5 | 27 | 7.5 | 10 |
| 10 | 29 | 7.0 | 6 |
| 20 | 27 | 8.0 | 4.6 |

The volume fraction of grain boundaries can be determined using the following equation given by Palumbo et al., Aust, Scripta Metall-Matev. 24(1990), 1347, 2347
V^{gb}=[3 Δ(d−Δ)²]/d³ (Eq. 1)

Where Δ is the grain boundary thickness and d is the average diameter of the grains. If one chooses 10 nm for the average grain size and a grain boundary width of 0.32 nm, as known, the volume fraction of grain boundaries in 0.09, or 9%, of the film. If 40% of the grain boundaries are sp² bonded, then 3.6% of the film is sp², assuming all sp² bonded carbon atoms are in the grain boundaries. A 30% increase in sp² character as given by the UV Raman equates to 4.7% of the film being sp² (0.036×1.3). If 9% of the carbon atoms in the film are in the grain boundaries, this means that (0.0468/0.09)=0.52 or 52% of the grain boundaries would have to be sp² bonded to rationalize the UV Raman data. These calculations based on experimental values demonstrate the inventors' belief that nitrogen preferentially enters the grain boundary and that the neighboring bonds change from a four-coordinated (sp³) to a three-coordinated (sp²) configuration.

There are several possible reasons for nitrogen incorporation to improve the field emission characteristics. The inventors' experiments show an increase in the number of sp² bonds with nitrogen incorporation. The increase in the number sp² bonds may lower the activation energy for conduction by, for example, increasing the density of states within the band gap of diamond. The transport of electrons to the vacuum interface may be enhanced by increased connectivity within the grain boundaries through an increase in sp² bonding. Both phenomena acting in concert may reduce a barrier for the emission of electrons.

These experiments show that nitrogen incorporated into UNCD their films lower the onset fields from diamond thin films to 5 V/μm or less, making it a potential candidate for field emission displays.

Recent density-functional based tight-binding (DFTB) calculations have been performed, which may explain the increase in the sp²:sp³ in the films with nitrogen and show that nitrogen substitution into the grain boundaries rather than into the diamond lattice, is energetically favorable by 2.6 to 5.6 eV, depending on the specific grain boundary site. The calculations suggest that three-fold coordinated sites are the lowest energy sites for nitrogen and that these promote sp² bonding in the neighboring carbon. The theoretical calculations are thus in agreement with the experimental results, which show a 25-30% relative increase in sp² bonding.

In summary, nitrogen-doped UNCD thin films have been synthesized using a microwave plasma CVD technique with a CH₄/Ar/N₂ gas mixture. Other carbon containing gases also are applicable, as well as other deposition methods and other noble gases, as previously stated. The morphology and transport properties of the films are both greatly affected by the presence and amount of CN in the plasma, which varies as N₂ gas is added. The HRTEM data indicated that the grain size and GB width of the UNCD films increase with the addition of N₂ in the plasma. Our transport measurements indicate that these films have the highest n-type electrical conductivity reported thus far in phase-pure diamond thin films.

The electrochemical characterization reveals that these films have a wide working potential window in aqueous media (˜4V), a very low background voltammetric signal, and excellent activity for several aqueous-based redox analytes without any pretreatment. Cyclic voltammetric ΔEₚ-values of 60 to 90 mV (0.1 V/s) for Fe(CN)₆^{-3/-4}, Ru(NH₃)₆^{+3/+2} and methyl viologen are observed. Evidence for the important role of the sp²-bonded carbon atoms in the grain boundaries, thus removing the Tr bonding. The electrochemical response for the redox analytes is almost totally inhibited after 60 minutes of treatment due to excessive film resistance caused by the loss of the π bonding.

FIG. 8A shows a series of visible Raman spectra for films deposited with and without N₂ in the source gas mixture. FIG. 8B shows the spectrum for a microcrystalline diamond film, for comparison. Three bands are observed for all four nanocrystalline films (FIG. 8A): 1125, 1339 and 1560 cm⁻¹. The broad band at 1339 cm⁻¹ is assigned to the first-order phonon mode for diamond, reflective of the sp³-bonded microstructure. The peak is shifted to higher wavenumbers from the expected 1332 cm⁻¹ position. Normally, microcrystalline diamond films have a sharp peak at 1332±2 cm⁻¹ with a linewidth of 5 to 8 cm⁻¹ (FIG. 8B). The significantly broadened and shifted diamond line for the nanocrystalline films results from the decreasing grain size to the nanometer scale. To a first approximation, the linewidth is a measure of the phonon lifetime. The more defects there are (i.e., grain boundaries), the shorter the phonon lifetime and the broader the linewidth. The amorphous sp²-bonded carbon peak at 1560 cm⁻¹ results from the π-bonded carbon atoms in the grain boundaries. The position and intensity of this broad peak depends on the deposition conditions used, the wavelength of the excitation photon and how microstructurally ordered the nondiamond carbon phase is. The spectra also contain a feature centered at 1125 cm⁻¹. Broadening and shifting of the diamond band as the grain size decreases to the nanometer level, with the concomitant development of scattering intensity in the 1400-1600 cm⁻¹ region is observed. The latter is due to an increasing fraction of π-bonded carbon atoms in the grain boundaries being probed. The band at 1125 cm⁻¹ is a characteristic feature of nanocrystalline diamond but an unequivocal assignment has not been made. Semiquantitative analysis of the Raman data was performed and the results are presented in Table 2.

TABLE 2
Visible Raman spectroscopic peak intensity ratios for
nanocrystalline diamond films.

| Film | I₁₃₃₉/I₁₅₆₀ | I₁₃₃₉/I₁₁₂₅ | I₁₅₆₀/I₁₁₂₅ |
|---|---|---|---|
| 1% CH₄/99% Ar | 1.45 | 2.27 | 1.59 |
| 1% CH₄/2% N₂/99% Ar | 1.29 | 2.33 | 1.89 |
| 1% CH₄/4% N₂/99% Ar | 1.30 | 2.44 | 1.89 |
| 1% CH₄/5% N₂/99% Ar | 1.30 | 2.65 | 2.10 |

The relative intensity ratios of the three peaks in the nanocrystalline diamond spectra are shown as a function of the N₂ percentage in the source gas mixture. It can be seen that the ratio of the diamond to the nondiamond band intensities, I₁₃₃₉/I₁₅₆₀, is largest for the film deposited without N₂ and decreases for the films deposited with the gas. Interestingly, the ratio is independent of the N₂ level. An assumption is often made that the relative band intensities reflect the volume fractions of diamond and nondiamond carbon present. In making this assumption, one must consider that the optical probing depth (i.e., sampled volume) can vary with the microstructure of the nondiamond phase. Also, the scattering cross sections for the different types of nondiamond carbon phases possible (mixtures of sp²- and sp³-bonded carbon) are unknown. Therefore, these data should be used in a relative not an obsolute sense.

The decrease in the I₁₃₃₉/I₁₅₆₀ intensity ratio when N₂ is added results from the increased fraction of π-bonded carbon atoms in the grain boundaries. The trends in the I₁₃₃₉/I₁₁₂₅ and I₁₅₆₀/I₁₁₂₅ band intensity ratios and the N₂ added are interesting and more difficult to interpret. The data reveal that both the diamond and nondiamond band intensities relative to the 1125 cm⁻¹ band intensity with increasing levels of N₂. In other words, both the diamond and nondiamond peaks grow in intensity, relative to the 1125 cm⁻¹ peak, with decreasing grain or cluster size. If the 1125 cm⁻¹ intensity were directly related to defect-induced states brought about by the nanocrystalline morphology, then one would expect this intensity to increase with the decreasing grain or cluster size. Therefore, we suppose that this peak results from a film property other than defect-induced states. The effect of film thickness, grain and cluster size, temperature and the wavelength of the excitation photon will need to be studied systematically to better understand the origins of this band.

FIG. 9 shows the UV Raman spectra for films deposited from CH₄/Ar with N₂ added. The use of visible excitation often gives rise to an intense background luminescence that can mask the Raman line in nanocrystalline diamond, even in films with low sp² carbon content. Also, the Raman signal for sp²-bonded carbon (amorphous or graphitic) is approximately 50 times more sensitive than diamond using visible excitation (514.5 nm). The signal for diamond is expected to increase relative to that for amorphous or graphitic carbon as the excitation wavelength is shifted toward the UV. For example, the spectrum for a 1% CH₄/1% N/98% Ar film shows a moderately intense diamond line at 1332 cm⁻¹ with a linewidth of 25 cm⁻¹. There is no band present at 1125 cm⁻¹ (this region of the spectrum is not shown), but there is a broad band centered near 1550 cm⁻¹, due to the sp²-bonded carbon in the grain boundaries. The band intensities for the diamond and nondiamond carbon are roughly the same, but the peak area for the latter is significantly larger. The sp³/sp² band intensity ratios are 1.0, 0.56, and 0.25 for the 1%, 5%, and 10% N₂ levels, respectively, indicating that the fraction of Tr-bonded grain boundaries increase with N₂ added.

FIGS. 10A and B show dynamic SIMS data for the nitrogen and carbon atomic concentrations in the nanocrystalline films. The actual nitrogen and carbon atomic concentrations, as well as the N/C atomic ratios, are listed in Table 3.

TABLE 3
Secondary ion mass spectrometry data for nanocrystalline
diamond films.

| Film | N(atoms/cm³) | C(atoms/cm³) | N/C |
|---|---|---|---|
| 1% CH₄/99% Ar | 7.88 × 10¹⁸ | 1.32 × 10²² | 5.97 × 10⁻⁴ |
| 1% CH₄/1% N₂/97% Ar | 1.89 × 10²⁰ | 1.29 × 10²² | 1.46 × 10⁻² |
| 1% CH₄/2% N₂/97% Ar | 2.30 × 10²⁰ | 1.29 × 10²² | 1.96 × 10⁻² |
| 1% CH₄/5% N₂/97% Ar | 5.30 × 10²⁰ | 1.20 × 10²² | 4.42 × 10⁻² |
| 1% CH₄/10% N₂/97% Ar | 4.17 × 10²⁰ | 1.22 × 10²² | 3.42 × 10⁻² |

FIG. 10A shows a plot of the N/C atomic ratio versus the percentage of N₂ in the source gas mixture. There is a near linear increase in the ratio with N₂ added up to the 5% level. Above 5%, the amount incorporated levels off. The N/C for 0% N₂ in the source gas mixture is not zero but rather 5.97×10-4; about two orders of magnitude lower than the ratio in the films deposited from gas mixtures containing N₂. FIG. 10B shows profiles of the carbon and nitrogen concentrations as a function of depth for a film approximately 1 μm thick. The concentration of nitrogen is as high as approximately 5×10²⁰ atoms/cm³ with uniform distribution through the film.

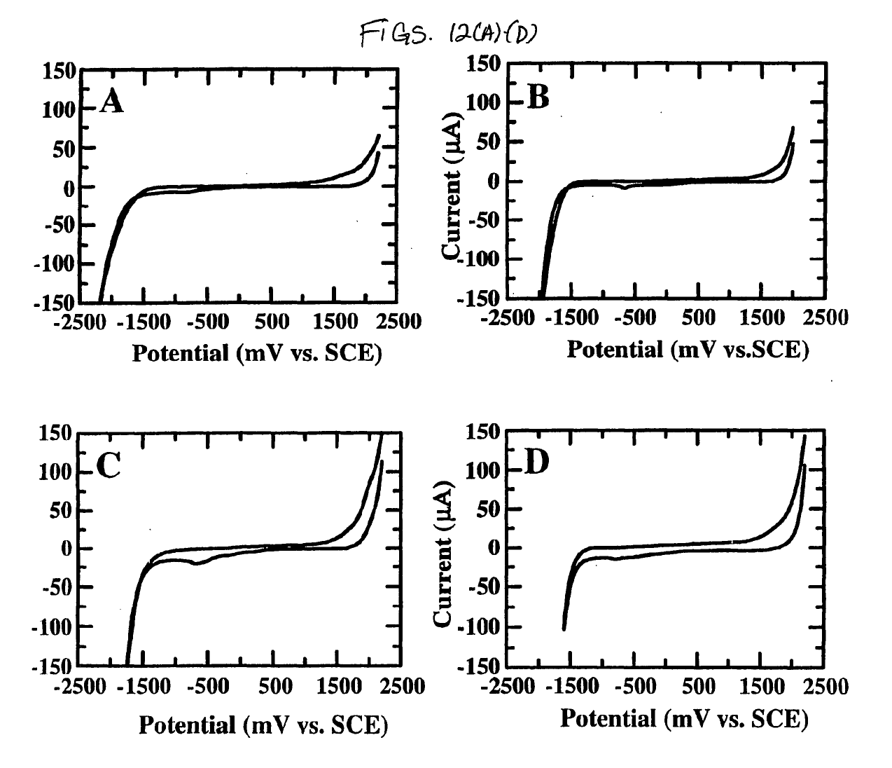

FIG. 11 shows a series of cyclic voltammetric i-E curves in 1 M KCl for nanocrystalline diamond films containing different levels of incorporated nitrogen. It is clear that the responses between −500 and 1000 mV are very similar irrespective of the level of nitrogen incorporated. The background currents are low and featureless within this potential range. Each is also unchanging with cycle number indicating that the surface structure is stable. The magnitude of the anodic current at 250 mV is approximately 0.4 μA or 2.0 μA/cm² (geom.) for all of the nanocrystalline films. This is slightly lower than the 2.7 μA/cm² reported previously for nanocrystalline diamond films deposited from C₆₀/A₆. For comparison, the background current for polished glassy carbon at this potential and scan rate is near 20 μA/cm₂. In summary, very minor differences are seen in the background voltammograms between −500 and 1000 mV with varying levels of incorporated nitrogen. This indicates that the excess surface charge density int his potential region is not affected significantly by the nitrogen concentration, and the introduction of nitrogen in the grain boundaries does not introduce detectable levels of electroactive carbon sites.

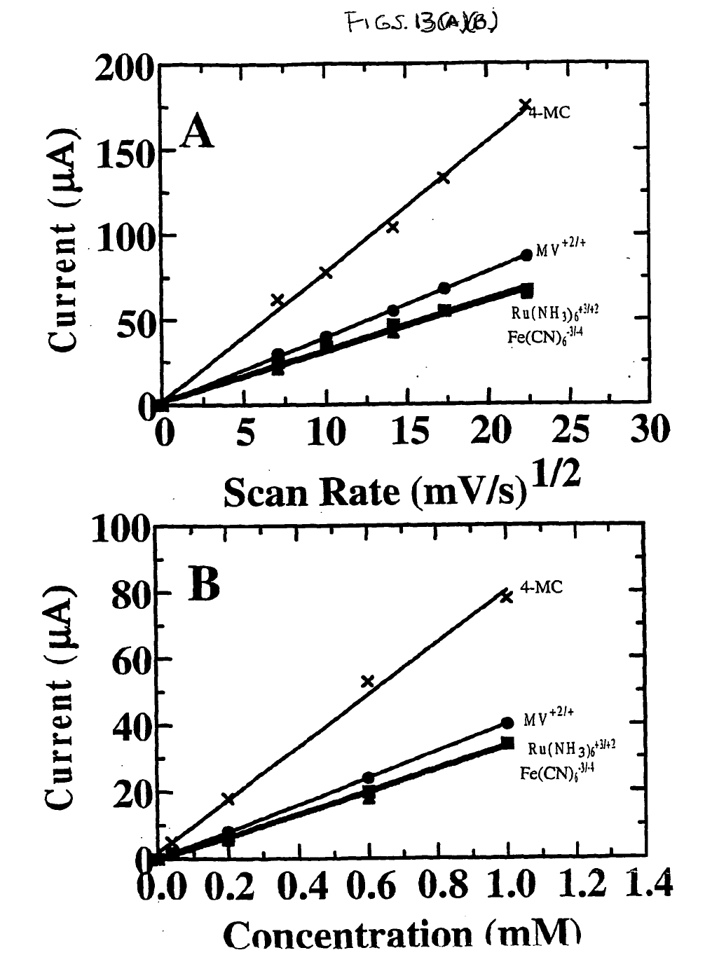

FIGS. 12(A)-(D) show cyclic voltammetric i-E curves in 0.1 M HClO₄ for nanocrystalline diamond films containing different levels of incorporated nitrogen. The voltammograms cover a wider potential range than those in FIG. 11, allowing determination of the full working potential window. All the films have an anodic limit of approximately 2400 mV (100 μA or 500 μA/cm²). The current at this potential is mainly due to oxygen evolution and, to a much lesser extent, the oxidation of carbon atoms on the surface. The surface oxidation processes may involve both the diamond and grain boundary carbon, and are evidenced indirectly by the anodic charge passed between 1400 and 2200 mV just prior to the exponentially increasing current for oxygen evolution. Previously, we have reported a well defined anodic peak near 1.6 V for C₆₀/Ar nanocrystalline films, and have attributed this peak to the oxidation of sp²-bonded grain boundary carbon atoms. However, the currents for this proposed redox process in the present films are much lower than what was reported previously. The main difference between the nitrogen-containing films is the apparent overpotential for hydrogen evolution. There is a progressive decrease in the overpotential for hydrogen evolution (−100 μA or −500 μA/cm²) with increasing levels of incorporated nitrogen. The films deposited with 0, 2, 4 and 5%. N₂ added to the source gas mixture have working potential windows of 4.27, 4.05, 3.85 and 3.78 V, respectively.

The electrochemical activity of the nitrogen-containing films was probed using Fe(CN)₆^{-3/-4}, Ru(NH₃)₆⁺³⁺², methyl viologen and 4-methylcatechol. The voltammetric response of these and other aqueous-based analytes at clean, boron-doped microcrystalline diamond has been discussed in detail previously.

TABLE 4
Cyclic voltammetric ΔEₚ values for
nanocrystalline diamond film.

| | Fe | Ru | | | |
|---|---|---|---|---|---|
| Film | (CN)₆^{-3/-4} | (NH3)₆^{+2/+3} | MV^{+2/+1} | 4-MC | R(Ω) |
| 1% CH₄/99% Ar | 103 | 219 | 100 | 201 | 1535 ± 30 |
| 1% CH₄/2% N₂/ | 93 | 73 | 54 | 382 | 177 ± 3 |
| 97% Ar | | | | | |
| 1% CH₄/4% N₂/ | 91 | 69 | 50 | 312 | 106 ± 7 |
| 97% Ar | | | | | |
| 1% CH₄/5% N₂/ | 88 | 61 | 51 | 387 | 81 ± 4 |
| 97% Ar | | | | | |

Table 4 shows the cyclic voltammetric ΔEₚ values at 0.1 V/s with iR correction. It can be seen that the largest uncompensated resistance, most of which is the bulk resistance of the electrode, is observed for the 1% CH₄/99% Ar film. The uncompensated resistance is significantly lower for the films containing nitrogen with a trend of decreasing resistance with increasing nitrogen incorporation. The iR corrected data reveal that the ΔEₚ values for methyl viologen, Ru(NH₃)₆^{+3/+2} and Fe(CN)₆^{-2/-3} all decrease with increasing nitrogen incorporation. These relatively low ΔEₚ's were obtained even though the films received no pretreatment prior to use. This reflects the material's chemical inertness and resistance to fouling by adsorbed impurities.

The rate of electron transfer for Fe(CN)₆^{-3/-4} at metal and sp² carbon electrodes is strongly affected several factors. First, the rate is strongly influenced by the fraction of edge plane exposed on sp² carbon electrodes (i.e., electronic properties), but relatively insensitive to the surface-oxygen functionalities terminating the edge plane carbon atoms as long as a thick oxide film is not present. The rate of electron transfer increases proportionally with the fraction of exposed edge plane, as detected by Raman spectroscopy. Second, surface cleanliness is important as is the electrolyte type and concentration. For example, the involvement of specifically adsorbed cations (e.g., K⁺) through a possible surface-bridging interaction has been proposed. The rate of electron transfer increases with electrolyte composition in the order of LiCl [symbol] NaCl [symbol] KCl. At the 1 m electrolyte concentration, the rate is about a factor of 10 higher in KCl than in LiCl at both gold and glassy carbon electrodes. Third, adsorbed monolayers on sp² carbon electrodes can decrease the rate of electron transfer. It has been observed the Δ(ΔEₚ) increase from 5 to 140 mV after modification of the polished grassy carbon surface with adsorbed monolayers. The level of increase depends on the type and coverage of the adsorbate.

The rate of electron transfer is also influenced by the physiochemical properties of boron-doped diamond. ΔEₚ is very sensitive to the surface termination with the smallest ΔEₚ observed at the clean, hydrogen-terminated surface. After oxygen termination, Δ(ΔEₚ) increases by over 125 mV but it is reversibly reduced to the original value after removal of the oxygen functionalities by hydrogen plasma treatment (42). The sensitivity of the kinetics to surface oxygen is in sharp contrast to the minor effects these functionalities have on the response at sp² carbon electrodes. The rate of electron transfer is also sensitive to the electrolyte composition and ionic strength with the largest rates observed in Kcl and the smallest in LiCl. However, the difference at the 1 M concentration level is only a factor of 2 to 3 rather than 10, as is the case for metal and glassy carbon electrodes. All the evidence at sp² carbon and diamond electrodes suggest the involvement of some non-oxide surface site. Typical ΔEₚ values of 85 to 95 mV for the nitrogen-incorporated nanocrystalline diamond indicate that these films possess the requisite surface structure, chemical composition and electronic properties to support rapid electron transfer for this particular mechanistically-complicated redox system.

The rate of electron transfer for Ru(NH₃)₆^{+3/+2}, in contrast with Fe(CN)₆^{-3/-4}, is relatively insensitive to the surface microstructure, surface oxides and adsorbed monolayers on sp² carbon electrodes. The rate of electron transfer is insensitive to surface modification with the strong implication that electron transfer does not depend on an interaction with a surface site or functional group. The most important factor affecting the rate of electron transfer is the electronic properties of the electrode, specifically the density of electronic states near the formal potential of the redox system. Of course with metal and glassy carbon electrodes, a low density of electronic states is never an issue. However, with the semiconducting/semimetallic properties of diamond, the potential-dependent electronic density of states is an influential factor. This is why ΔEₚ values of 60 to 75 mV are good in agreement with the 70 to 80 mV values often observed for boron-doped microcrystalline diamond films at 0.1 V/s.

The formal potential (i.e., cyclic voltammetric E_{p/2} value) for this couple is −218 mV vs. SCE. The valence band position of boron-doped microcrystalline diamond has been estimated to be approximately 550 mV vs. SCE. Given the 5.5 eV bandgap and the assumption that the interfacial energetics of nanocrystalline diamond are similar, this means that the formal potential falls within the bandgap (i.e., between the valence and conduction band positions). Therefore, this redox system is not expected to exchange charge directly with either the valence or the conduction band. The nearly reversible response indicates that there must be a high density of electronic states present within the bandgap at this potential. These electronic states arise from the nitrogen incorporated and or/the nitrogen-related defects introduced. Theoretical work will be discussed below which indicates the bandgap density of electronic states arises from the Tr-bonded carbon in the grain boundaries.

Methyl viologen also involves simple outer sphere electron transfer at diamond and most other electrodes. The rate of electron transfer at diamond is relatively insensitive to surface oxides, grain boundaries and defect density, and the presence of nondiamond carbon impurities. Like Ru(NH₃)₆^{+3/+2}, the most important factor influencing the rate of electron transfer is the density of electronic states at the formal potentials for the two redox reactions. Nearly reversible voltammetric behavior (ΔEₚ's from 60 to 90 mV at 0.2 V/s) is typically observed for both the MV⁺²/MV⁺ and MV⁺/MV⁰ redox couples having a formal potentials of −725 and −1050 mV vs. SCE, respectively. MV can form surface phases depending on the experimental conditions and these deposits complicate the process of directly relating the ΔEₚ to the rate of electron transfer. The formal potentials are well into the bandgap region, even more negative than the formal potential for Ru(NH₃)₆^{+3/+2}. The relatively low ΔEₚ of 50 to 60 mV for nitrogen-incorporated nanocrystalline diamond indicates these electrodes contain a high density of bandgap electronic states, even these negative potentials.

4-methylcatechol exhibits more electrochemical irreversibility as evidenced by the ΔEₚ of 200 to 400 mV. Also, there is a trend of increasing ΔEₚ with increasing nitrogen-incorporation. The more irreversible behavior is also characteristic of all the catechols and catecholamines investigated so far at microcrystalline diamond. Typical ΔEₚ values of 450 to 700 mV at 0.1 V/s are observed. For comparison, ΔEₚ at polished glassy carbon under identical conditions is in the range of 125 to 175 mV (36). The formal potential is positive of that for Fe(CN)₆^{-3/-4} so a low density of electronic states is not the reason for the large ΔEₚ. The ΔEₚ at microcrystalline diamond is largely unaffected by chaning the surface termination from hydrogen to oxygen leading to the conclusion that surface carbon-oxygen functionalities are not influential. We believe a lack of adsorption on diamond is one of the reasons for the relatively slow electrode kinetics. Recent voltammetric and coulometric studies of several catechols and catecholamines revealed no evidence for adsorption even at solution concentrations as low as 2 μM. Indirect support for this belief also comes from the knowledge that other polar analytes, such as 2,6-anthraquinone-disulfonate, adsorb weakly on diamond at very low coverages. A detailed study has been presented showing that low ΔEₚ values correlate with catechol and catecholamine adsorption on glassy carbon, and surface treatments that decreased adsorption also increased ΔEₚ.

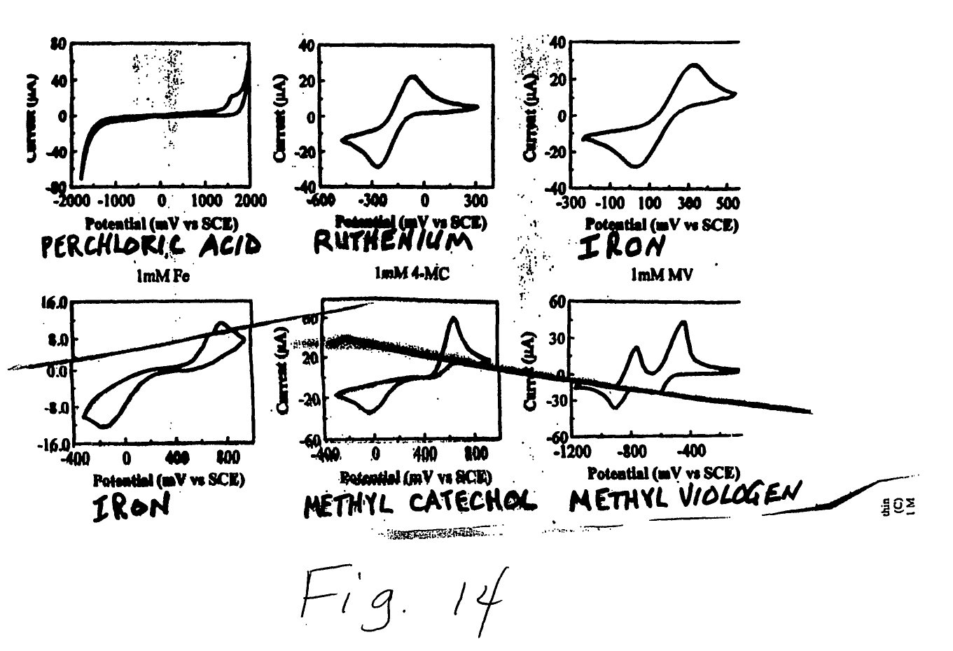

FIGS. 13(A) and (B) show plots of the voltammetric oxidation peak current as a function of the square root of the scan rate and the solution concentration for all four redox analytes. In all cases, the peak current varies linearly with the square root of the scan rate (r² [symbol] 0.995) and all plots intercept the y-axis near the origin. This indicates the reactions are limited by semi-infinite linear diffusion of the reactant to the electrode. The voltammetric peak current also varies linearly with the concentrations (r²) 0.992) for all analytes from the 0.1 to 1 mM level. All plots intercept the y-axis near the origin, as expected.

Electrochemically, these films are excellent electrodes. They are characterized by a wide working potential window (˜4 V), low background current and a very active response for Fe(CN)₆^{-3/-4}, Ru(NH₃)₆^{+/+2} and MV^{+2/+} without any conventional pretreatment. ΔEₚ's in the range of 60 to 90 mV (0.1 V/s) are observed for these three redox systems depending on the nitrogen incorporation. ΔEₚ for 4-MC was significantly larger at 200 to 400 mV (0.1 V/s) indicative of slower electrode reaction kinetics compared to the other three redox systems.

Ultrananocrystalline diamond films doped with nitrogen to render them electrically conducting can be used as electrochemical electrodes which span a potential range of over 4 eV in aqueous solutions such as 0.1M HClO₄. FIGS. 12(A)-(D) shows cyclic voltammetric i-E curves for films deposited from source gas mixtures of methane and vapor containing different amount of nitrogen.

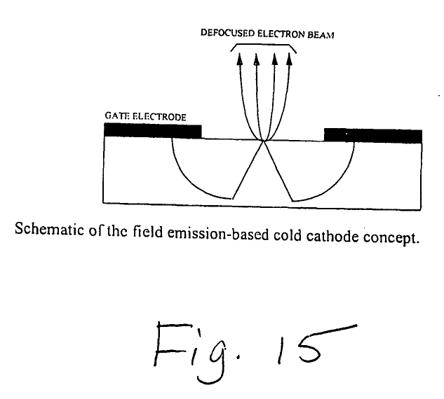

The n-UNCD electrodes are useful for a wide range of oxidation reduction reactions as illustrated in FIG. 14 for Fe(CN)₆^{-3/-4}, Ru(NH₃)₆^{+3/+2}, IrCl₆^{-2/-3}, and methyl violagen with a high degree of electrochemical activity. More sluggish electrode kinetics are observed for 4-methylcatechol. Apparent heterogeneous electron transfer rate constants of 10⁻² to 10⁻¹cm/5 are observed for the highly active reactions without any pretreatment.

The fact that continuous pinhole free n-type UNCD films can be grown at thicknesses at least an order of magnitude lower than 4 p-type microcrystalline diamond make the UNCD electrode extremely useful for industrial applications.

While particular embodiments of the present invention have been shown and described, it will be appreciated by those skilled in the art that changes and modifications may be made without departing from the invention in its broader aspects.

Therefore, the aim in the appended claims is to cover all such changes and modifications as fall within the true spirit and scope of the invention. The matter set forth in the foregoing description and accompanying drawings is offered by way of illustration only and not as a limitation. The actual scope of the invention is intended to be defined in the following claims when viewed in their proper perspective based on the prior art.

The embodiments of the invention in which an exclusive property or privilege is claimed are defined as follows:

1. An electrode having a surface of an electrically conducting ultrananocrystalline diamond having not less than 10¹⁹ atoms/cm³ nitrogen with an electrical conductivity at ambient temperature of not less than about 0.1 (Ω·cm)⁻¹.

2. The electrode of claim 1, wherein the ultrananocrystalline diamond is a film.

3. The electrode of claim 1, wherein the ultrananocrystalline diamond has grain boundaries that are about 0.2 to about 2.0 nm wide and the conductivity at ambient temperature is not less than about 1 (Ωcm)⁻¹.

4. The electrode of claim 1, wherein the conductivity at ambient temperature is not less than about 10 (Ωcm)⁻¹.

5. The electrode of claim 1, wherein the film has a thickness less than about 2000 Å and is substantially pin-hole free.

6. The electrode of claim 1, wherein the source of carbon is one or more of CH₄ or a precursor thereof and C₂H₂ or a precursor thereof and a C₆₀ compound.

7. The electrode of claim 6, wherein the nitrogen is present in the source gas in an amount of less than about 20% by volume.

8. The electrode of claim 7, wherein the atomic percent of carbon in the source gas is about 1% and the nitrogen is present in an amount less than about 25% by volume, the balance being a nobel gas.

9. An electrode having a surface of an electrically conducting ultrananocrystalline diamond having an average grain size of about 15 nm or less and nitrogen present in an amount of not less than about 10¹⁹ atoms/cm³ made by the process of providing a source of carbon and a source of nitrogen and subjecting the sources of carbon and nitrogen in vapor form to an energy source in an noble-gas atmosphere to create a plasma to form an ultrananocrystalline material, wherein carbon is present in an amount less than about 2 atom percent of the source gas.

10. The electrode of claim 9, wherein the ultrananocrystalline diamond is a film having a thickness less than about 2000 Å.

11. A method of remediating aqueous solutions having toxic material therein, comprising subjecting the aqueous solution having toxic material therein to an electrical potential between two electrodes, at least one of which has a surface of an electrically conducting ultrananocrystalline diamond having not less than 10¹⁹ atoms/cm³ nitrogen with an electrical conductivity at ambient temperature of not less than about 0.1 (Ω·cm)⁻¹.

12. A method of stimulating nerves comprising establishing an electrical potential across the nerve using an electrode conducting ultrananocrystalline diamond having not less than 10¹⁹ atoms/cm³ nitrogen with an electrical conductivity at ambient temperature of not less than about 0.1 (Ω·cm)⁻¹.

13. An electron emission device incorporating an electrically conducting ultrananocrystalline diamond having not less than 10¹⁹ atoms/cm³ nitrogen with an electrical conductivity at ambient temperature of not less than about 0.1 (Ω·cm)⁻¹.

14. The electron emission device of claim 13, wherein the device is a cold cathode used in one or more of a flat panel display, a traveling wave tube, and electrical instrument such as mass spectrometers or electron microscopes, ion beam accelerators, an x-ray machine, in a thruster or a sensor in a semiconductor-based sensor or actuation device.

15. An electrochemical cell having an anode and a cathode and an aqueous based electrolyte wherein at least one of said anode or cathode has a surface of an electrically conducting ultrananocrystalline diamond having not less than 10¹⁹ atoms/cm³ nitrogen with an electrical conductivity at ambient temperature of not less than about 0.1 (Ω·cm)⁻¹.
